(19) United States
(12) Patent Application Publication
(10) Pub. No.: US 2007/0176304 A1
(43) Pub. Date: Aug. 2, 2007

(54) Regularly-aligned nano-structured material and method for producing the same

(75) Inventor: Koukichi Waki, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 11/642,538

(22) Filed: Dec. 21, 2006

(30) Foreign Application Priority Data
Dec. 21, 2005 (JP) 2005-367720
Mar. 29, 2006 (JP) 2006-091712

(51) Int. Cl. H01L 23/29

(52) U.S. Cl. 257/789

(57) ABSTRACT

A nano-structured material comprising a depression/projection-patterned substrate and a sol-gel film having at least one group selected from the group consisting of an alkyl group, a phenyl group, an epoxy group and an amino group in the depressions of the patterned substrate, wherein polystyrene particles having a particle size of from 10 to 200 nm, or holes having a hole size of from 10 to 200 nm that may be filled with nanoparticles are regularly aligned in the depressions of the patterned substrate.

### BACKGROUND OF THE INVENTION

1. Field of the Invention

The present invention relates to a nano-structured material, in particular to a nano-structured material with polystyrene particles regularly aligned therein, a nano-structured material with nano-holes regularly aligned therein, and a nano-structured material with nano particles-filled nano-holes regularly aligned therein.

2. Description of the Related Art

It is well known that, when a substance is micro-divided into fine particles having a diameter of an order of from a few to tens nanometers, then it may express a property different from its property in a bulky state. For example, known are significant melting point depression and quantum effect expression, and taking advantage of these phenomena, various applied techniques are now being much developed. Concrete examples of the applications are high-functional composite materials, catalysts, non-linear optical materials, memory devices, etc., and the applications may cover various technical fields of many aspects.

For efficiently utilizing the specific properties of such fine particles, it is an extremely natural idea to prepare a two-dimensional or three-dimensional array by regularly aligning individual particles and to construct a device by utilizing the array, and it is being much studied these days.

The recent development of scanning probe microscopes and the like has made it possible to manipulate and align individual particles, but this is not practicable for industrial application as its producibility is poor.

For promoting alignment of particles, a method may be taken into consideration which comprises aligning particles on a previously-patterned substrate. Photolithography may be effective for the patterning method, but it is well known that the patterning limit in conventional lithography is to the dimension of less than 100 nm (e.g., Lithography for ULSI (Okazaki, Proceeding of SPIE, Vol. 2440, p. 18)).

For patterning with fine particles having a size of from a few to tens nanometers, the wavelength of the light source to be applied to them must be shortened, but it is said that even a deep ultraviolet (DUV) light source is limited to a particle size of 50 nm or so. Direct writing systems including more short-waved extreme-UV lithography, X-ray lithography, or electron beam or scanning probe lithography are being developed, but they all require a vast capital investment for both the light source and the assistant optical system for them. In addition, such direct writing systems have another drawback in that their production takes an enormous time as being a successive process.

U.S. Pat. No. 6,265,021 discloses an alignment method with a synthetic DNA lattice, but the method requires an expensive equipment investment for the process for lattice formation and for DNA automatic synthesis.

JP-A-10-261244, JP-A-2002-353432, JP-A-2004-193523 and JP-A-2003-268592 disclose a nano-structure with anodic oxidation alumina. According to the disclosed method, however, it is difficult to produce a regular structure having a large area, and the method is defective in that it may give an irregular domain structure aggregation.

JP-A-2001-168317, JP-A-2003-67919 and JP-A-2003-168606 disclose a regularly-aligned film produced through adsorption by thiol molecules, but the method could hardly give a regular structure having a large area and is therefore also defective in that it may give an irregular domain structure aggregation.

JP-A-2003-247081 discloses a self-organizing film with a dendrimer. However, like that in the above method with thiol molecules, the film is also defective in that it has an irregular domain structure and could not be a regularly-aligned large-area film.

JP-A-2001-151834 discloses a regularly-patterning material that relies on micro-phase separation of a block copolymer, but this method is also defective in that it could hardly produce a large-area regular structure and the material may form an irregular domain structure aggregation.

JP-A-2004-122283 discloses a method of forming fine pores in a material layer by the use of a nano-indicator having conical pressure elements. This may give a large-area regular structure with ease, but in this, it is extremely difficult to align the conical pressure elements so as to be regularly spaced from each other in accordance with the intended nano-structure to be constructed.

JP-A-2003-183849 discloses a method for producing a regular structure by aligning polystyrene particles. JP-A-2003-318010 discloses a method for producing a regular structure by applying a mixed solution of a hydrophobic polymer and an amphipathic polymer in an organic solvent onto a substrate, and imparting a high-humidity vapor thereto at a constant flow rate thereby vaporizing fine droplets of water vapor condensed through vaporization of the organic solvent. In both methods, an irregular structure could not be removed, and it is desired to improve them in this point.

### SUMMARY OF THE INVENTION

In view of the background problems as above, an object of the invention is to provide a nano-structured material regularly aligned over a large area. In particular, the invention is to provide the nano-structured material regularly aligned over a large area that may be produced at a low cost. Another object of the invention is to provide a method for producing such a nano-structured material at a low cost in a simplified manner.

We, the present inventors have found that, when polystyrene particles having a particle size of from 10 to 200 nm are regularly aligned in the depressions of a patterned substrate which is produced by applying a heat-resistant film-forming material onto a substrate and drying it thereon, and then pressing a patterned mold thereto and heating and molding the material, or in the depressions of a patterned substrate which is produced by pressing a patterned mold onto a substrate, then casting a heat-resistant film-forming material into the space between the substrate and the mold and heating an molding the material therebetween, then an excellent nano-structured material can be produced. On the basis of these findings, we have completed the present invention.

Specifically, the above-mentioned problems can be solved by the following invention:

A nano-structured material comprising a depression/projection-patterned substrate and a sol-gel film having at least one group selected from the group consisting of an alkyl group, a phenyl group, an epoxy group and an amino group in the depressions of the patterned substrate, wherein polystyrene particles having a particle size of from 10 to 200 nm, or holes having a hole size of from 10 to 200 nm that may be filled with nanoparticles are regularly aligned in the depressions of the patterned substrate.

The present invention particularly includes the following embodiments:

### Embodiment 1

A nano-structured material comprising a depression/projection-patterned substrate and a sol-gel film having at least one group selected from the group consisting of an alkyl group, a phenyl group, an epoxy group and an amino group in the depressions of the patterned substrate, wherein polystyrene particles having a particle size of from 10 to 200 nm are regularly aligned in the depressions of the patterned substrate.

### Embodiment 2

A nano-structured material comprising a depression/projection-patterned substrate and a sol-gel film having at least one group selected from the group consisting of an alkyl group, a phenyl group, an epoxy group and an amino group in the depressions of the patterned substrate, wherein holes having a hole size of from 10 to 200 nm are regularly aligned in the depressions of the patterned substrate.

### Embodiment 3

A nano-structured material comprising a depression/projection-patterned substrate and a sol-gel film having at least one group selected from the group consisting of an alkyl group, a phenyl group, an epoxy group and an amino group in the depressions of the patterned substrate, wherein holes having a hole size of from 10 to 200 nm that are filled with nanoparticles are regularly aligned in the depressions of the patterned substrate.

### Embodiment 4

The nano-structured material of any one of embodiments 1 to 3, wherein the patterned substrate and the sol-gel film are formed of the same material and are integrated together.

### Embodiment 5

The nano-structured material of any one of embodiments 1 to 4, wherein the nanoparticles are of a material selected from the group consisting of metal, metal sulfide, metal oxide and polymer.

### Embodiment 6

A method for producing a nano-structured material of any one of embodiments 1 to 5, which comprises preparing a patterned substrate with a sol-gel film having at least one group selected from the group consisting of an alkyl group, a phenyl group, an epoxy group and an amino group at least in the depressions of the patterned substrate, and regularly aligning polystyrene particles having a particle size of from 10 to 200 nm in the depressions of the patterned substrate.

### Embodiment 7

The method for producing a nano-structured material of embodiment 6, which comprises applying a heat-resistant film-forming material onto a substrate and drying the applied material thereon, and then pressing a patterned mold to the material and heating and molding the pressed material on the substrate to produce the depression/projection-patterned substrate.

### Embodiment 8

The method for producing a nano-structured material of embodiment 6, which comprises pressing a patterned mold to a substrate, then casting a heat-resistant film-forming material into the space between the substrate and the mold, and heating and molding the material therebetween to produce the depression/projection-patterned substrate.

### Embodiment 9

The method for producing a nano-structured material of embodiment 7 or 8, wherein the patterned substrate is formed of a sol-gel film having at least one group selected from the group consisting of an alkyl group, a phenyl group, an epoxy group and an amino group.

### Embodiment 10

The method for producing a nano-structured material of any one of embodiments 6 to 9, which additionally comprises applying a heat-resistant film-forming material onto the layer of regularly-aligned polystyrene particles, heating and molding the material thereon, and thereafter etching the material and dissolving the polystyrene particles to form heat-resistant nano-holes.

### Embodiment 11

A nano-structured material produced according to the production method of any one of embodiments 6 to 10.

The invention provides a nano-structured material regularly aligned over a large area, at a low cost in a simplified manner. The nano-structured material of the invention can be effectively utilized in various fields of high-functional composite materials, catalysts, non-linear optical materials, memory devices, etc.

### BEST MODE FOR CARRYING OUT THE INVENTION

The nano-structured material of the invention is described in detail hereinunder. The description of the constitutive elements of the invention given hereinunder may be for some typical embodiments of the invention, to which, however, the invention should not be limited. In this description, the numerical range expressed by the wording “a number to another number” means the range that falls between the former number indicating the lowermost limit of the range and the latter number indicating the uppermost limit thereof.

The invention is described in detail hereinunder, in an order of the nano-structured material with polystyrene particles regularly aligned therein, the nano-structured material with nano-holes regularly aligned therein, and the nano-structured material with nano-holes regularly aligned therein in which the holes are filled with nanoparticles.

Nano-Structured Material with Regularly-Aligned Polystyrene Particles:

The nano-structured material of the first embodiment of the invention is characterized in that it has a sol-gel film having at least one group selected from an alkyl group, a phenyl group, an epoxy group and an amino group in the depressions of the depression/projection-patterned substrate thereof and that polystyrene particles having a particle size of from 10 to 200 nm are regularly aligned in the depressions.

The depression/projection-patterned substrate for use in the invention may be any one of which the surface projections and depressions are patterned, and its details are not specifically defined. The pattern for use in the invention is not also specifically defined, and may be determined in any desired manner in accordance with its use. The production method for the patterned substrate is not also specifically defined. In general, it is desirable that the patterned substrate is produced by applying a heat-resistant film-forming material onto a substrate, then drying it thereon, and pressing a patterned mold to it, and heating and molding the material; or by casting a heat-resistant film-forming material into the space between the substrate and the mold, and heating and molding the material therebetween.

The heat-resistant film-forming material is preferably at least one film-forming material selected from the group consisting of organosilica sol, organotitania sol, silicone resin, and inorganic/organic hybrid sol.

The dispersion solvent for the organosilica sol and the organotitania sol is preferably alcohols such as methanol, ethanol, n-propanol, isopropanol, n-butanol; or alkanes such as hexane, heptane, octane, benzene, toluene, xylene.

The silicone resin is preferably soluble in various solvents, such as Torayfil R190 (by Toray-Silicone), Adeka Nanohybrid Silicone (by Asahi Denka Kogyo).

The inorganic/organic hybrid sol includes three types of a dispersion-type sol, a pendant-type sol, and a copolymer-type sol, and any of these is usable in the invention. In consideration of its high heat resistance, a pendant-type sol or a copolymer-type sol is preferred for use herein.

The inorganic/organic hybrid sol preferred for use in the invention is a hydrolyzate of a silane compound of the following general formula (1) and/or a partial condensate thereof.
(R¹⁰)ₘ—Si(X)₄₋ₘ (1)
wherein R¹⁰ represents a substituted or unsubstituted alkyl group, or a substituted or unsubstituted aryl group; X represents a hydroxyl group or a hydrolyzable group, such as an alkoxy group (preferably an alkoxy group having from 1 to carbon atoms, such as a methoxy group, an ethoxy group), a halogen atom (e.g., chlorine, bromine, iodine), or R²COO (where R² is preferably a hydrogen atom or an alkyl group having from 1 to 5 carbon atoms, such as CH₃COO, C₂H₅COO), preferably an alkoxy group, more preferably a methoxy group or an ethoxy group; m indicates an integer of from 0 to 3; when the formula has plural R¹⁰'s and plural X's, then the plural R¹⁰'s and the plural X's may be the same or different. m is preferably 1 or 2, more preferably 1.

Not specifically defined, the substituent in R¹⁰ includes a halogen atom (e.g., fluorine, chlorine, bromine), a hydroxyl group, a mercapto group, a carboxyl group, an epoxy group, an alkyl group (e.g., methyl group, ethyl group, i-propyl group, propyl group, tert-butyl group), an aryl group (e.g., phenyl group, naphthyl group), an aromatic heterocyclic group (e.g., furyl group, pyrazolyl group, pyridyl group), an alkoxy group (e.g., methoxy group, ethoxy group, i-propoxy group, hexyloxy group), an aryloxy group (e.g., phenoxy group), an alkylthio group (e.g., methylthio group, ethylthio group), an arylthio group (e.g., phenylthio group), an alkenyl group (e.g., vinyl group, 1-propenyl group), an acyloxy group (e.g., acetoxy group, acryloyloxy group, methacryloyloxy group), an alkoxycarbonyl group (e.g., methoxycarbonyl group, ethoxycarbonyl group), an aryloxycarbonyl group (e.g., phenoxycarbonyl group), a carbamoyl group (e.g., carbamoyl group, N-methylcarbamoyl group, N,N-dimethylcarbamoyl group, N-methyl-N-octylcarbamoyl group), an acylamino group (e.g., acetylamino group, benzoylamino group, acrylamino group, methacrylamino group). These substituents may be further substituted.

When the formula has plural R¹⁰'s, then it is desirable that at least one of them is a substituted alkyl group or a substituted aryl group. Especially preferred are vinyl-polymerizing substituent-having organosilane compounds of the following general formula (2):

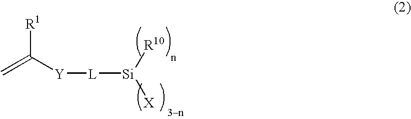

In formula (2), R¹ represents a hydrogen atom, a methyl group, a methoxy group, an alkoxycarbonyl group, a cyano group, a fluorine atom or a chlorine atom. The alkoxycarbonyl group includes a methoxycarbonyl group and an ethoxycarbonyl group. R¹ is preferably a hydrogen atom, a methyl group, a methoxy group, a methoxycarbonyl group, a cyano group, a fluorine atom or a chlorine atom, more preferably a hydrogen atom, a methyl group, a methoxycarbonyl group, a fluorine atom or a chlorine atom, even more preferably a hydrogen atom or a methyl group.

Y represents a single bond, or an ester group, an amido group, an ether group or a urea group. Preferably, Y is a single bond or an ester group or an amido group, more preferably a single bond or an ester group, even more preferably an ester group.

L represents a divalent linking chain. Concretely, it includes a substituted or unsubstituted alkylene group, a substituted or unsubstituted arylene group, a substituted or unsubstituted alkylene group having a linking group (e.g., ether group, ester group, amido group) inside it, a substituted or unsubstituted arylene group having a linking group inside it; preferably a substituted or unsubstituted alkylene group, a substituted or unsubstituted arylene group, or an alkylene group having a linking group inside it; more preferably an unsubstituted alkylene group, an unsubstituted arylene group, or an alkylene group having an ether group or an ester group; still more preferably an unsubstituted alkylene group, or an alkylene group having an ether or ester group. The substituent includes a halogen atom, a hydroxyl group, a mercapto group, a carboxyl group, an epoxy group, an alkyl group, an aryl group; and these substituents may be further substituted.

n indicates 0 or 1. When the formula has plural X's, then the plural X's may be the same or different. n is preferably 0.

R¹⁰ has the same meaning as in formula (1), and is preferably a substituted or unsubstituted alkyl group, or an unsubstituted aryl group, more preferably an unsubstituted alkyl group or an unsubstituted aryl group.

X has the same meaning as in formula (1), and is preferably a halogen atom, a hydroxyl group or an unsubstituted alkoxy group, more preferably a chlorine atom, a hydroxyl group, or an unsubstituted alkoxy group having from 1 to 6 carbon atoms, even more preferably a hydroxyl group, or an alkoxy group having from 1 to 3 carbon atoms, still more preferably a methoxy group.

Two or more different types of the compounds of formulae (1) and (2) may be combined for use herein. Specific examples of the compounds of formulae (1) and (2) are mentioned-below, to which, however, the invention should not be limited.

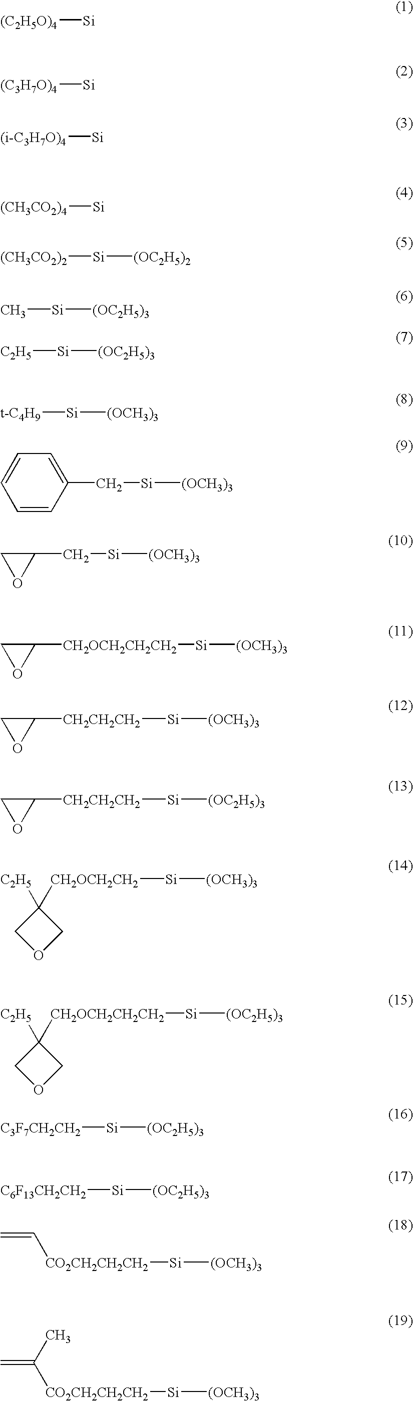

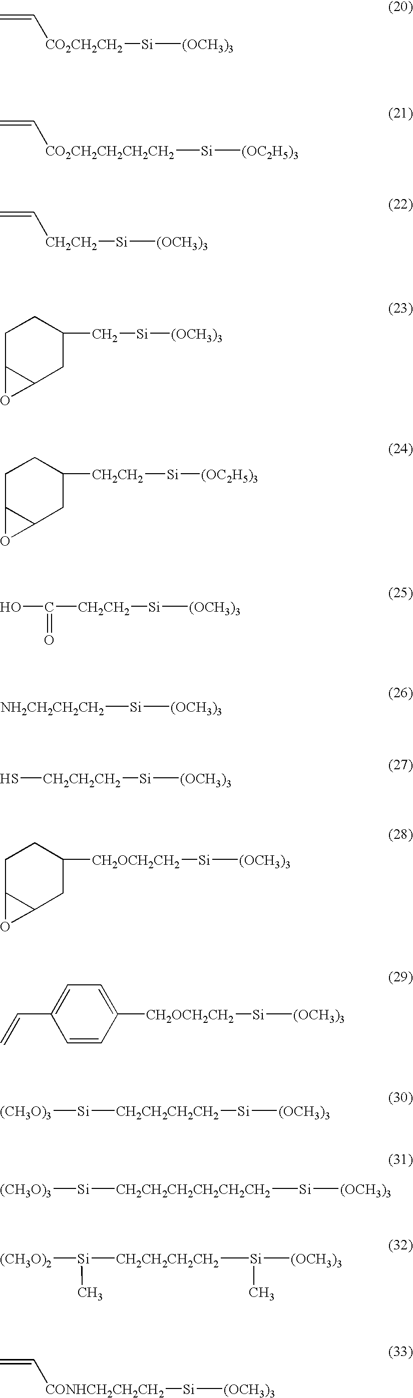

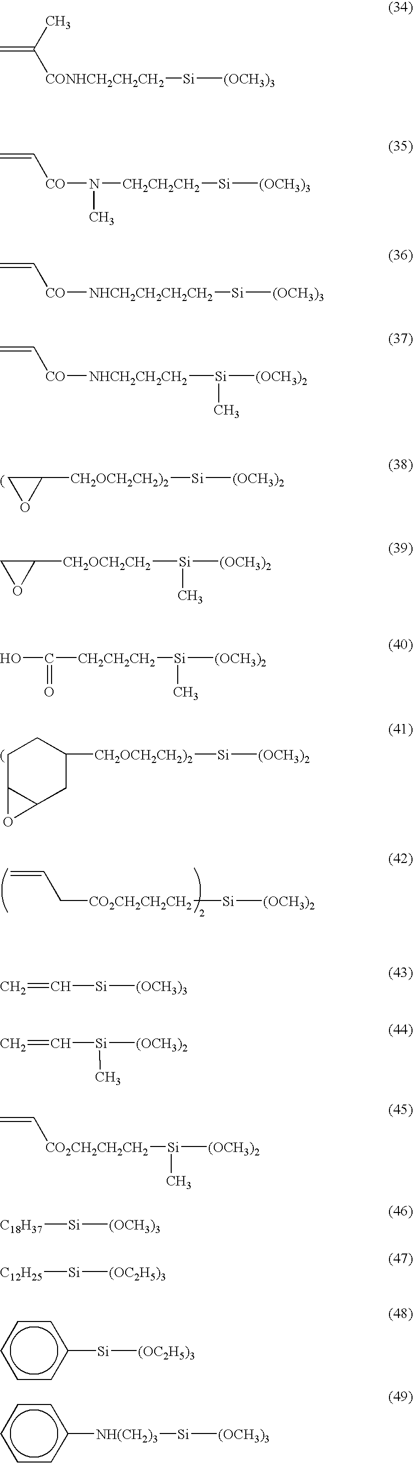

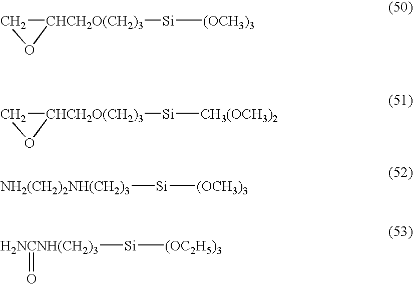

Hydrolysis and condensation of the silane compound may be attained in the absence or presence of a solvent, but is preferably attained in an organic solvent for uniformly mixing the ingredients therein. For example, preferred are alcohols, aromatic hydrocarbons, ethers, ketones, ester. Preferably, the solvent dissolves both the silane compound and the catalyst used. Also preferably, the solvent may be used as the coating solution or as a part of the coating solution in view of the process of producing the material of the invention.

Of those, the alcohols include, for example, monoalcohols and dialcohols. The monoalcohol is preferably a saturated aliphatic alcohol having from 1 to 8 carbon atoms. Examples of the alcohols are methanol, ethanol, n-propyl alcohol, i-propyl alcohol, n-butyl alcohol, sec-butyl alcohol, tert-butyl alcohol, ethylene glycol, diethylene glycol, triethylene glycol, ethylene glycol monomethyl ether, ethylene glycol monobutyl ether, ethylene glycol acetate monomethyl ether.

Examples of the aromatic hydrocarbons are benzene, toluene, xylene; examples of the ethers are tetrahydrofuran, dioxane; examples of the ketones are acetone, methyl ethyl ketone, methyl isobutyl ketone, diisobutyl ketone; examples of the esters are ethyl acetate, propyl acetate, butyl acetate, propylene carbonate.

One or more different types of these organic solvents may be used herein as combined. Not specifically defined, the concentration of the solid matter in the reaction may be generally from 1% by mass to 90% by mass, preferably from 20% by mass to 70% by mass.

Preferably, the silane compound is hydrolyzed and condensed in the presence of a catalyst. The catalyst includes inorganic acids such as hydrochloric acid, sulfuric acid, nitric acid; organic acids such as oxalic acid, acetic acid, formic acid, methanesulfonic acid, toluenesulfonic acid; inorganic bases such as sodium hydroxide, potassium hydroxide, ammonia; organic bases such as triethylamine, pyridine; metal alkoxides such as triisopropoxyaluminium, tetrabutoxyzirconium. In view of the production stability of the sol liquid and of the storage stability of the sol liquid, preferred is an acid catalyst (inorganic acid, organic acid). The inorganic acid is preferably hydrochloric acid or sulfuric acid; and the organic acid is preferably one having an acid dissociation constant in water (pKa, at 25° C.) of at most 4. 5. More preferred are hydrochloric acid, sulfuric acid, an organic acid having an acid dissociation constant in water of at most 3.0; even more preferred are hydrochloric acid, sulfuric acid, an organic acid having an acid dissociation constant in water of at most 2.5; still more preferred is an organic acid having an acid dissociation constant in water of at most 2.5; further more preferred are methanesulfonic acid, oxalic acid, phthalic acid, malonic acid; even further preferred is oxalic acid.

The hydrolysis/condensation may be effected generally as follows: Water is added to a silane compound in an amount of from 0.3 to 2 mols, preferably from 0.5 to 1 mol relative to one mol of the hydrolyzable group of the silane compound, and stirred in the presence or absence of the above-mentioned solvent, preferably in the presence of a catalyst, at 25 to 100° C.

When the hydrolyzable group is an alkoxide and the catalyst is an organic acid, then the amount of water to be added to the reaction system may be reduced since the carboxyl group or the sulfo group of the organic acid may feed a proton to the system. The amount of water to be added relative to one mol of the alkoxide group of the silane compound may be generally from 0 to 2 mols, preferably from 0 to 1. 5 mole, more preferably from 0 to 1 mol, even more preferably from 0 to 0.5 mols. When an alcohol is used as the solvent, then addition of no water to the system may be preferred.

The amount of the catalyst to be used is described. When the catalyst is an inorganic acid, then its amount to be used may be generally from 0.01 to 10 mol %, preferably from 0.1 to 5 mol %; and when the catalyst is an organic acid, then its optimum amount may vary depending on the amount of water added to the system. In the latter case where water is added to the system, the amount of the catalyst may be generally from 0.01 to 10 mol %, preferably from 0.1 to 5 mol % of the hydrolyzable group; but where no water is substantially added thereto, then the amount of the catalyst may be generally from 1 to 500 mol %, preferably from 10 to 200 mol %, more preferably from 20 to 200 mol %, even more preferably from 50 to 150 mol %, still more preferably from 50 to 120 mol % of the hydrolyzable group.

The reaction may be attained by stirring the system generally at 25 to 100° C., but preferably, the reaction condition is suitably controlled depending on the reactivity of the silane compound.

The thickness of the gel film formed of the hydrolyzate and/or its partial condensate sol of the silane compound for use in the invention may be generally from2 to 100 nm, preferably from 5 to 50 nm.

The heating temperature at which the hydrolyzate and/or its partial condensate sol of the silane compound of the invention is gelled into a film may be generally from 100 to 250° C., preferably from 120 to 200° C.

The pattern profile of the mold for use in the invention may have concentric circular, trapezoidal, rectangular or square projections of which one side is generally from 0.1 to 100 μm, preferably from 0.1 to 60 nm, more preferably from 0.1 to 30 nm, and have grooves generally having a width of from 10 nm to 10 μm and a depth of from 2 to 100 nm, between them. The width of the grooves is preferably from 10 nm to 6 μm, more preferably from 10 nm to 3 μm; and the depth of the grooves is preferably from 2 to 60 nm, more preferably from 2 to 30 nm.

Preferably, the mold for use in the invention has a peelable surface. Preferably, it is formed of quartz glass or silicone water optionally surface-treated with a metal or an organic matter.

The substrate for use in the invention may be any one formed of an inorganic substance, an organic substance or a composite. Concretely, usable for it are aluminium, magnesium alloys, glass, quartz, carbon, silicon, ceramics, polyesters (e.g., polyethylene terephthalate, polyethylene naphthalate), polyolefins, cellulose triacetates, polycarbonates, aliphatic polyamides, aromatic polyamides, polyimides, polyamidimides, polysulfones, polybenzoxazoles.

The heat-resisting temperature of the substrate is preferably 300° C. or higher. More preferably, any suitable one is selected from those mentioned above.

Preferably, the substrate is smooth, having a surface roughness (Ra) of at most 5 nm, more preferably at most 2 nm. Also preferably, a rough substrate may be coated with a undercoat layer so that it may have a smooth surface.

The nano-structured material of the invention is characterized in that it has a sol-gel film having at least one group selected from an alkyl group, a phenyl group, an epoxy group and an amino group, in the depressions of the depression/projection-patterned substrate thereof.

The material to form the sol-gel film having at least one group selected from an alkyl group, a phenyl group, an epoxy group and an amino group in the invention is a material that contains a silane-coupling agent, concretely octadecyltrimethoxysilane, dodecyltriethoxysilane, phenyltriethoxysilane, γ-anilinopropyltrimethoxysilane, γ-glycidoxypropyltrimethoxysilane, γ-glycidoxypropylmethyldimethoxysilane, γ-(2-aminoethyl)aminopropyltrimethoxysilane, γ-ureidopropyltriethoxysilane (corresponding to the above-mentioned compounds (46) to (53)), (3-aminopropyl)dimethylethoxysilane, (3-aminopropyl)dimethylmethoxysilane, (3-aminopropyl)ethyldiethoxysilane, (3-aminopropyl)triethoxysilane, γ-(2-aminoethyl)aminopropylmethyldimethoxysilane. These are commercially available, and their commercial products may be used herein.

The sol-gel film in the depressions has at least one group selected from an alkyl group, a phenyl group, an epoxy group and an amino group, preferably an amino group. The alkyl group preferably has from 3 to 20 carbon atoms, more preferably from 5 to 18 carbon atoms. The hydrogen atom that constitute the alkyl group, the phenyl group, the epoxy group and the amino group may be substituted with any other substituent than a hydrogen atom. Preferably, however, the groups are unsubstituted.

In the invention, after the depression/projection-patterned substrate has been formed according to the above-mentioned process, a sol-gel film having at least one group selected from an alkyl group, a phenyl group, an epoxy group and an amino group may be formed in the depressions (first production method). Alternatively, the depression/projection-patterned substrate formed of a sol-gel film with at least one group selected from an alkyl group, a phenyl group, an epoxy group and an amino group may be directly produced (second production method). In the invention any of these methods may be employed favorably.

In the first production method where a sol-gel film having at least one group selected from an alkyl group, a phenyl group, an epoxy group and an amino group is formed in the depressions of the patterned substrate, for example, employable is air-doctor coating, blade coating, rod coating, extrusion coating, air-knife coating, squeeze-coating, dip-coating, reverse roll coating, transfer roll coating, gravure coating, kiss-coating, cast-coating, spray-coating or spin-coating. For these methods, for example, referred to is Newest Coating Technology (issued by Sogo Gijutsu Center, May 31, 1983). Above all, preferably employed is spin-coating or dip-coating.

In the first production method, the heat-resistant film-forming material to be used in forming the patterned substrate may be the same as or different from the material to be used in forming the sol-gel film, but preferably it differs from the latter. Concretely, as compared with the heat-resistant film-forming material for use in producing the patterned substrate, it is desirable that the material to be used in forming the sol-gel film has the property of more readily adsorbing polystyrene particles.

The second production method is simple and economical as compared with the first production method in that the former gives the material of the invention in one stage. According to the second production method, the patterned substrate and the sol-gel film are formed of the same material and they are integrated together. The wording “formed of the same material” as referred to herein means that, in the second production method, there is no difference between the patterned substrate and the sol-gel film in the material composition of the two, differing from the first production method, but this does not include composition change that may be caused by surface oxidation after production. Regarding the details of the second production method, directly referred to is the description relating to the production method for the depression/projection-patterned substrate given hereinabove.

In the nano-structured material of the invention, polystyrene particles having a particle size of from 10 to 200 nm are regularly aligned. As regularly aligned, the polystyrene particles are adsorbed by the sol-gel film having at least one group selected from an alkyl group, a phenyl group, an epoxy group and an amino group. When the particles are applied to a substrate not having an adsorbent layer thereon, then they may readily aggregate and are therefore hardly aligned regularly.

The polystyrene particles for use in the invention have a particle size of from 10 to 200 nm, preferably from 10 to 100 nm, more preferably from 10 to 50 nm. When the particle size is too large, then the nano-structured material would lose its meaning and it may be produced by any other method, and therefore the invention may have few advantages. On the other hand, when the particle size is too small, then it would be difficult to uniformly produce such small polystyrene particles. Preferably, the polystyrene particles for use herein have a narrow particle size distribution. Concretely, the particle size fluctuation coefficient (this is a value obtained by dividing the standard deviation by the mean particle size and expressed as percentage) is preferably at most 15%, more preferably at most 10%. When the fluctuation coefficient is too large, then it is unfavorable since regular alignment of the particles would be difficult. Preferably, the polystyrene particles for use in the invention are spherical.

Various methods may be employed for applying a dispersion of polystyrene particles onto a substrate in the invention. Concretely, the same method as that for sol-gel film formation mentioned above may be employed.

Nano-Structured Material with Regularly-Aligned Nano-Holes:

The nano-structured material of the second embodiment of the invention is characterized in that it has a sol-gel film having at least one group selected from an alkyl group, a phenyl group, an epoxy group and an amino group in the depressions of the depression/projection-patterned substrate thereof and that holes having a hole size of from 10 to 200 nm (hereinafter referred to as nano-holes) are regularly aligned in the depressions.

Preferably, the regularly-aligned nano-holes in the invention are formed by applying the above-mentioned heat-resistant film-forming material onto the layer with polystyrene particles regularly aligned thereon, as mentioned above, then heating and molding it thereon, and thereafter etching it and dissolving the polystyrene particles.

The etching may be either dry etching such as ion etching, or wet etching with a chemical capable of dissolving the film,

For dissolving the polystyrene particles, various organic solvents may be used, preferably benzene, toluene, xylene, carbon tetrachloride, methyl ethyl ketone or cyclohexanone.

Nano-Structured Material with Regularly-Aligned Nano-Holes Filled with Nano-Particles:

The nano-structured material of the third embodiment of the invention is characterized in that it has a sol-gel film having at least one group selected from an alkyl group, a phenyl group, an epoxy group and an amino group in the depressions of the depression/projection-patterned substrate thereof and that the depressions have regularly-aligned nano-holes with nanoparticles of from 10 to 200 nm in size filled therein.

The nanoparticles for use in the invention may be selected in any desired manner, depending on the intended nano-structured material. Preferably, they are one or more nanoparticles selected from the group consisting of metals, metal sulfides, metal oxides and polymers.

Examples of the metal are single metals or alloys of Ag, Au, Pt, Pd, Cu, Ru. Examples of the metal sulfide are ZnS, CdS, PdS, In₂S₃, Au₂S, Ag₂S, FeS. Examples of the metal oxide are TiO₂, SiO₂, Ag₂O, Cr₂O₃, ZrO₂, SnO₂, MnO. The polymer for the nanoparticles may be any one not specifically defined.

Preferably, the nanoparticles for use in the invention are magnetic nanoparticles having a mean diameter of from 2 to 20 nm. Examples of the magnetic nanoparticles are FePt, CoPt, FePd, Fe₂O₃, Fe₃O₄, Sm₂Fe₁₇N₃, SmCo₅, Nd₂Fe₁₄B. These magnetic nanoparticles have a high magnetic anisotropy constant and may have a high coercive force and good thermal stability even though they have a small size, and therefore they are effectively used for magnetic recording. They may form a regularly-aligned nano-structure, and the nano-structure may be used as an ultra-high-density, high-capacity magnetic recording medium.

The nanoparticles may be filled in the regularly-aligned nano-holes by applying their dispersion onto the nano-holes. For applying the dispersion onto the nano-holes, the same method as that mentioned hereinabove for applying the polystyrene particles dispersion may be employed.

Preferably, the nanoparticles dispersion contains at least one dispersant having from 1 to 3 groups of an amino group, a carboxyl group, a sulfonic acid group or a sulfinic acid group, in an amount of from 0.001 to 10 mols per mol of the nanoparticles. When containing the dispersant of the type added thereto, the nanoparticles dispersion may be more highly monodispersed with no coagulation.

The dispersant includes compounds of R—NH₂, NH₂—R—NH₂, NH₂—R(NH₂)—NH₂, R—COOH, COOH—R—COOH, COOH—R(COOH)—COOH, R—SO₃H, SO₃H—R—SO₃H, SO₃H—R(SO₃H)—SO₃H, R—SO₂H, SO₂H—R—SO₂H, SO₂H—R(SO₂H)—SO₂H. In these formulae, R represents a linear, branched or cyclic, saturated or unsaturated hydrocarbon.

Oleic acid is especially preferred for the dispersant. Oleic acid is a well-known surfactant for colloid stabilization, and is used for protecting metal particles such as iron. The relatively long chain of oleic acid (for example, oleic acid have a chain of 18 carbon atoms, and its length is about 2 nm; and oleic acid is not aliphatic but has one double bond) gives important steric hindrance for canceling the strong magnetic interaction between particles.

Similar ling-chain carboxylic acids such as erucic acid and linolic acid may also be used like oleic acid (for example, one or more long-chain organic acids having from 8 to 22 carbon atoms may be used either singly or as combined). Oleic acid (e.g., olive oil) is favorable as it is an easily-available inexpensive natural resource. Oleylamine derived from oleic acid is also an useful dispersant like oleic acid.

### EXAMPLES

The characteristics of the invention are described more concretely with reference to the following Examples. In the following Examples, the material used, its amount and ratio, the details of the treatment and the treatment process may be suitably modified or changed not overstepping the sprit and the scope of the invention. Accordingly, the invention should not be limited to the Examples mentioned below.

### Example 1

Preparation of Organosilane Sol Composition:

100 g of acryloyloxypropyltrimethoxysilane (compound (18)) was dissolved in 121 g of methyl ethyl ketone in a reactor equipped with a stirrer and a reflux condenser, and 0.125 g of hydroquinone monomethyl ether, 5.86 g of aluminium ethylacetacetate diisopropylate (30% by mass) and 23.0 g of water (H₂O) were added thereto and mixed, then reacted at 60° C. for 3 hours, and thereafter cooled to room temperature to obtain a sol composition. The sol was entirely oligomers or higher polymers (having a weight-average molecular weight of from 1000 to 2000).

Formation of Nano-Structured Material with Regularly-Aligned Polystyrene Spherical Particles—1

A quartz glass mold of which the entire surface was so worked that, on the circumference thereof separated from the center by a distance of from 25 mm to 60 mm, concentric circles having an arc length on the center side of 5 μm and having a width of 2 μm are configured entirely thereon as spaced from each other by a groove having a width of 250 nm and a depth of 20 nm, was pressed against a glass substrate having a surface roughness (Ra) of 0.5 nm, using a presser; and in the thus-formed depressions on the substrate, the above-mentioned sol composition that had been diluted with 2-ethoxyethanol to have a concentration of 1% by mass, was cast, and then heated as such at 150° C. for 25 minutes. Next, while cooled rapidly, it was ultrasonically peeled off to produce a sol-gel film with concentric circles regularly aligned therein.

Next, a 2-ethoxyethanol solution of 0.005 mas. % γ-(2-aminoethyl)aminopropyltrimethoxysilane was dropwise applied onto the sol-gel film, and on a spin coater, this was rotated at 4000 rpm so that the grooves of the sol-gel film could be filled with the solution, and then dried at 60° C. for 25 minutes.

Next, a dispersion of 0.4 mas. % polystyrene spherical particles having a mean particle size of 50 nm (fluctuation coefficient of 10%) was dropwise applied to it, and on a spin coater, this was rotated at 4000 rpm, and then dried at 60° C. for 25 minutes.

The sample was observed with SEM (scanning electromicroscope, Hitachi's S-5200), which confirmed the formation of a nano-structured material with polystyrene spherical particles regularly aligned in the concentric arc grooves therein.

### Example 2

Formation of Nano-Structured Material with Regularly-Aligned Polystyrene Spherical Particles—2

A quartz glass mold of which the entire surface was so worked that, on the circumference thereof separated from the center by a distance of from 25 mm to 60 mm, concentric circles having an arc length on the center side of 2 μm and having a width of 500 nm are configured entirely thereon as spaced from each other by a groove having a width of 250 nm and a depth of 20 nm, was pressed against a glass substrate having a surface roughness (Ra) of 0.5 nm, using a presser; and in the thus-formed depressions on the substrate, the an octane solution of 1 mas. % Torayfil R910 (by Toray Silicone) was cast, and then heated as such at 150° C. for 25 minutes. Next, while cooled rapidly, it was ultrasonically peeled off to produce a polymer film with concentric circles regularly aligned therein.

Next, a 2-ethoxyethanol solution of 0.005 mas. % γ-(2-aminoethyl)aminopropyltrimethoxysilane was dropwise applied onto the polymer film, and on a spin coater, this was rotated at 4000 rpm so that the grooves of the sol-gel film could be filled with the solution, and then dried at 60° C. for 25 minutes.

Next, a dispersion of 0.4 mas. % polystyrene spherical particles having a mean particle size of 20 nm (fluctuation coefficient of 10%) was dropwise applied to it, and on a spin coater, this was rotated at 4000 rpm, and then dried at 60° C. for 25 minutes.

The sample was observed with SEM, which confirmed the formation of a nano-structured material with polystyrene spherical particles regularly aligned in the concentric arc grooves therein.

### Example 3

Formation of Nano-Structured Material with Regularly-Aligned Nano-Holes—1

The nano-structured material produced in Example 2 was irradiated with Ar cluster ion beams on its surface, whereby its surface was etched away to the depth of the radius of the polystyrene spherical particles. Then, the remaining polystyrene spherical particles were dissolved away with cyclohexanone applied thereto.

Thus formed, the nano-hole structured material was observed with SEM, which confirmed the formation of a nano-structured material with nano-holes regularly aligned therein.

### Example 4

Formation of Nano-Structured Material with Regularly-Aligned Nano-Holes Filled with Nanoparticles—1

A decan dispersion was prepared by making oleic acid adsorbed by FePt nanoparticles having a mean diameter of 5 nm (fluctuation coefficient of 8%) and dispersing the resulting nanoparticles in decane. Thus prepared, the decane dispersion was applied onto the regularly-aligned nano-hole structured material of Example 3, in a mode of spin coating. This was dried at 250° C. for 20 minutes to form a nano-structure.

Thus completed, the nano-structure was observed with SEM, which confirmed the formation of a regularly-aligned nano-structured material with FePt nano-particles filled in the regularly-aligned nano-holes therein.

Further, the nano-structured material was heated in a gaseous atmosphere of N₂+H₂ (5%) at 500° C. for 30 minutes, then cooled, and thereafter the above-mentioned composition that had been diluted to a concentration of 0.05% by mass was applied thereonto in a mode of spin coating at 4000 rpm, and then dried at 150° C. for 20 minutes.

As a result, a smooth ferromagnetic medium having a mean surface roughness (Ra) of 0.8 nm and a coercive force of 4200 Oe (oersted) was obtained.

### Comparative Example 1

In Example 1, the 2-ethoxyethanol solution of 0.005 mas. % γ-(2-aminoethyl)aminopropyltrimethoxysilane was directly applied onto the glass substrate, not forming the concentric circular structure, and on a spin coater, this was rotated at 4000 rpm so that the solution could be filled into the grooves of the sol-gel film, and then dried at 60° C. for 25 minutes. Next, polystyrene spherical particles were applied onto it, in the same manner as in Example 1, and then dried at 60° C. for 25 minutes.

As observed with SEM, this was a structured material having polystyrene spherical particles partially regularly aligned therein and having a random domain structure.

### Comparative Example 2

In Example 1, polystyrene spherical particles were applied onto the substrate, not applying γ-(2-aminoethyl)aminopropyltrimethoxysilane thereonto, and this was then dried at 60° C. for 25 minutes.

As observed with SEM, this was a structured material having a sea-island structure with particle aggregation in which the polystyrene spherical particles were not regularly aligned.

### Example 5

Formation of Nano-Structured Material with Regularly-Aligned Nano-Holes Filled with Nanoparticles—2

An octane dispersion of 3 mas. % of Au nanoparticles was prepared by making dodecanethiol adsorbed by Au nanoparticles having a mean diameter of 10 nm (fluctuation coefficient of 8%) and dispersing them in octane. The resulting octane dispersion was applied onto the regularly-aligned nano-holes of the structured material of Example 3, in a mode of spin coating at 3000 rpm. This was dried at 100° C. for 20 minutes to form a nano-structured material,

Thus completed, the nano-structured material was observed with SEM, which confirmed the formation of a nano-structured material with regularly-aligned Au nano-particles filled in the regularly-aligned nano-holes therein.

### Example 6

Formation of Nano-Structured Material with Regularly-Aligned Polystyrene Spherical Particles—3

An octane solution of 0.5 mas. % Torayfil R910 (by Toray Silicone) was applied onto a glass substrate having a surface roughness (Ra) of 0.5 nm, and dried. Then, a quartz glass mold of which the entire surface was so worked that, on the circumference thereof separated from the center by a distance of from 25 mm to 60 mm, concentric circles having an arc length on the center side of 2 μm and having a width of 500 nm are configured entirely thereon as spaced from each other by a groove having a width of 250 nm and a depth of 20 nm, was pressed against the thus-coated glass substrate, using a presser, and heated at 200° C. for 25 minutes. Next, while cooled rapidly, it was ultrasonically peeled off to produce a polymer film with concentric circles regularly aligned therein.

Next, a 2-ethoxyethanol solution of 0.05 mas. % octadecyltrimethoxysilane was dropwise applied onto the polymer film, and on a spin coater, this was rotated at 4000 rpm so that the grooves could be filled with the solution, and then dried at 150° C. for 25 minutes.

Next, a dispersion of 0.4 mas. % polystyrene spherical particles having a mean particle size of 20 nm (fluctuation coefficient of 10%) was dropwise applied to it, and on a spin coater, this was rotated at 4000 rpm, and then dried at 60° C. for 25 minutes.

The sample was observed with SEM, which confirmed the formation of a nano-structured material with polystyrene spherical particles regularly aligned in the concentric arc grooves therein.

### Example 7

Formation of Nano-Structured Material with Regularly-Aligned Polystyrene Spherical Particles—4

An octane solution of 0.5 mas. % octadecyltrimethoxysilane (by Tokyo Chemical) was applied onto a glass substrate having a surface roughness (Ra) of 0.5 nm, and dried. Then, a quartz glass mold of which the entire surface was so worked that, on the circumference thereof separated from the center by a distance of from 25 mm to 60 mm, concentric circles having an arc length on the center side of 2 μm and having a width of 500 nm are configured entirely thereon as spaced from each other by a groove having a width of 250 nm and a depth of 20 nm, was pressed against the thus-coated glass substrate, using a presser, and heated at 150° C. for 25 minutes. Next, while cooled rapidly, it was ultrasonically peeled off to directly produce a sol-gel film having an alkyl group in its depressions and having concentric circles regularly aligned therein.

Next, a dispersion of 0.4 mas. % polystyrene spherical particles having a mean particle size of 20 n (fluctuation coefficient of 10%) was dropwise applied to it, and on a spin coater, this was rotated at 4000 rpm, and then dried at 60° C. for 25 minutes.

The sample was observed with SEM, which confirmed the formation of a nano-structured material with polystyrene spherical particles regularly aligned in the concentric arc grooves therein.

### Example 8

Formation of Nano-Structured Material with Regularly-Aligned Nano-Holes—2

The nano-structured material produced in Example 7 was irradiated with Ar cluster ion beams on its surface, whereby its surface was etched away to the depth of the radius of the polystyrene spherical particles. Then, the remaining polystyrene spherical particles were dissolved away with cyclohexanone applied thereto.

Thus formed, the nano-hole structured material was observed with SEM, which confirmed the formation of a nano-structured material with nano-holes regularly aligned therein.

### Example 9

Formation of Nano-Structured Material with Regularly-Aligned Nano-Holes Filled with Nanoparticles—2

A decan dispersion was prepared by making oleic acid adsorbed by FePt nanoparticles having a mean diameter of 5 nm (fluctuation coefficient of 8%) and dispersing the resulting nanoparticles in decane. Thus prepared, the decane dispersion was applied onto the regularly-aligned nano-hole structured material produced in Example 8, in a mode of spin coating. This was dried at 250° C. for 20 minutes to form a nano-structure.

Thus completed, the nano-structure was observed with SEM, which confirmed the formation of a regularly-aligned nano-structured material with FePt nano-particles filled in the regularly-aligned nano-holes therein.

Further, the nano-structured material was heated in a gaseous atmosphere of N₂+H₂ (5%) at 500° C. for 30 minutes, then cooled, and thereafter a 2-ethoxyethanol solution of 0.01 mas. % octadecyltrimethoxysilane was applied thereonto in a mode of spin coating at 4000 rpm, and then dried at 150° C. for 20 minutes.

As a result, a smooth ferromagnetic medium having a mean surface roughness (Ra) of 0.8 nm and a coercive force of 4200 Oe (oersted) was obtained.

As described in detail hereinabove with reference to its preferred embodiments, the invention provides a nano-structured material regularly aligned over a large area at a low cost in a simplified manner. The nano-structured material of the invention can be effectively used in various fields of, for example, high-functional composite materials, catalysts, non-linear optical materials, memory devices, etc. Accordingly, the industrial applicability of the invention is great.

The present disclosure relates to the subject matter contained in Japanese Patent Application No. 367720/2005 filed on Dec. 21, 2005 and Japanese Patent Application No. 91712/2006 filed on Mar. 29, 2006, which are expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A nano-structured material comprising a depression/projection-patterned substrate and a sol-gel film having at least one group selected from the group consisting of an alkyl group, a phenyl group, an epoxy group and an amino group in the depressions of the patterned substrate, wherein polystyrene particles having a particle size of from 10 to 200 nm, or holes having a hole size of from 10 to 200 nm that may be filled with nanoparticles are regularly aligned in the depressions of the patterned substrate.

2. The nano-structured material according to claim 1, wherein the polystyrene particles having a particle size of from 10 to 200 nm are regularly aligned in the depressions of the patterned substrate.

3. The nano-structured material according to claim 1, wherein the holes having a hole size of from 10 to 200 nm are regularly aligned in the depressions of the patterned substrate.

4. The nano-structured material according to claim 1, wherein the holes having a hole size of from 10 to 200 nm that are filled with nanoparticles are regularly aligned in the depressions of the patterned substrate.

5. The nano-structured material according to claim 1, wherein the patterned substrate and the sol-gel film are formed of the same material and are integrated together.

6. The nano-structured material according to claim 1, wherein the nanoparticles are of a material selected from the group consisting of metal, metal sulfide, metal oxide and polymer.

7. A method for producing a nano-structured material of claim 2, which comprises preparing a patterned substrate with a sol-gel film having at least one group selected from the group consisting of an alkyl group, a phenyl group, an epoxy group and an amino group at least in the depressions of the patterned substrate, and regularly aligning polystyrene particles having a particle size of from 10 to 200 nm in the depressions of the patterned substrate.

8. The method for producing a nano-structured material according to claim 7, which comprises applying a heat-resistant film-forming material onto a substrate and drying the applied material thereon, and then pressing a patterned mold to the material and heating and molding the pressed material on the substrate to produce the depression/projection-patterned substrate.

9. The method for producing a nano-structured material according to claim 7, which comprises pressing a patterned mold to a substrate, then casting a heat-resistant film-forming material into the space between the substrate and the mold, and heating and molding the material therebetween to produce the depression/projection-patterned substrate.

10. The method for producing a nano-structured material according to claim 8, wherein the patterned substrate is formed of a sol-gel film having at least one group selected from the group consisting of an alkyl group, a phenyl group, an epoxy group and an amino group.

11. The method for producing a nano-structured material according to claim 7, which additionally comprises applying a heat-resistant film-forming material onto the layer of regularly-aligned polystyrene particles, heating and molding the material thereon, and thereafter etching the material and dissolving the polystyrene particles to form heat-resistant nano-holes.

12. A nano-structured material produced according to the method of claim 7.
